(19) United States
(12) Patent Application Publication
(10) Pub. No.: US 2006/0196417 A1
(43) Pub. Date: Sep. 7, 2006

(54) Gas distribution systems for deposition processes

(75) Inventors: Chia-Hui Lin, Taichung Hsien (TW); Shih-Hao Lo, Jhonghe City (TW); Tsang-Yu Liu, Kaohsiung City (TW); Szu-An Wu, Hsinchu City (TW); Cheng-Hui Yang, Keelung City (TW); Yi-Fang Lai, Taipei (TW); Chien Feng Lin, Sanchong City (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/070,149

(22) Filed: Mar. 3, 2005

(51) Int. Cl. C23C 16/00

(52) U.S. Cl. 118/715

(57) ABSTRACT

Gas distribution systems for deposition processes and methods of using the same. A substrate support member holding a substrate is disposed in a processing chamber. A plurality of first and second gas nozzles is connected to a gas distribution ring disposed in the processing chamber. The first gas nozzles provide a first reactant gas and include at least first and second outlet apertures. The second gas nozzles provide a second reactant gas and include third outlet apertures. The first outlet aperture is larger than the second outlet aperture, such that the first gas nozzle with the first outlet aperture creates an increased gas flow adjacent to a determined portion of the substrate to increase deposition from the first reactant gas on the determined portion of the substrate.

### BACKGROUND

The invention relates to apparatuses and methods for processing semiconductor substrates, and more particularly to gas distribution systems for deposition processes and methods of using the same.

The manufacturing of integrated circuit products comprises, among other things, the formation of layers of a variety of different types of material using a variety of different deposition processes, for example, chemical vapor deposition (CVD), high density plasma chemical vapor deposition (HDPCVD), low pressure chemical vapor deposition (LPCVD), plasma enhanced chemical vapor deposition (PECVD), etc. In some cases, these layers may be subsequently patterned by performing a variety of known photolithography and etching processes. In other cases, such layers may be formed to fill a previously formed trench-type feature. In order to fabricate high quality layers, the distribution of plasma gas inside a processing (or reaction) chamber is an important factor that determines the ultimate quality of the processed layers.

Unfortunately, in film deposition, deposition thickness may vary somewhat according to local processing parameters of current deposition tools. This thickness variation may be significant in 300 mm wafer application. For example, the maximum thickness variation may be approximately 60 nm for a target nominal thickness of approximately 700 nm. Thus, an improved gas distribution system of a deposition tool is called for.

U.S. Pat. No. 6,143,078 to Ishikawa et al., the entirety of which is hereby incorporated by reference, describes a gas distribution system for a CVD processing chamber comprising a first gas inlet and a second gas inlet. The first gas inlet provides a first gas at a first distance from the interior surface of the chamber. The second gas inlet provides a second gas at a second distance, less than the first distance. Thus, the second gas creates a higher partial pressure adjacent to the interior surface of the chamber to significantly reduce deposition from the first gas onto the interior surface.

U.S. Publication No. 2004/0083972 to Li et al., the entirety of which is hereby incorporated by reference, describes a deposition tool comprising a processing chamber, a wafer stage holding a wafer positioned therein, and a gas delivery system positioned in the chamber above a position where plasma is to be generated in the chamber, wherein substantially all of the reactant gas is delivered into the chamber via the gas delivery system.

U.S. Publication No. 2004/0103844 to Chou et al., the entirety of which is hereby incorporated by reference, describes a gas distribution system delivering plasma gas to a wafer reaction chamber. After setting a few control valve parameters, the gas distribution system automatically adjusts the distribution of plasma gas inside a wafer processing chamber during a film deposition process so that a uniform single wafer is produced. A main gas conduit is redirected into two separate gas conduits inside a gas separator. One conduit connects with a gas nozzle near the central region of an upper electrode panel distributor and the other conduit connects with a gas nozzle near the peripheral region of the upper electrode panel distributor. An O-ring between the central region and the peripheral region prevents any mixing of gas from the nozzles in these two regions.

### SUMMARY

Gas distribution systems for deposition processes and methods of using the same are provided. An exemplary embodiment of an apparatus for depositing a film on a substrate is provided. A substrate support member is disposed in a processing chamber. The substrate support member holds a substrate disposed thereon. A gas distribution ring is disposed in the processing chamber. A plurality of first gas nozzles is connected to the gas distribution ring, wherein the first gas nozzles are adapted to provide a first reactant gas and comprise at least first and second outlet apertures. A plurality of second gas nozzles is connected to the gas distribution ring, wherein the second gas nozzles are adapted to provide a second reactant gas and comprise third outlet apertures. The first aperture is larger than the second aperture.

An exemplary method of depositing a film on a substrate in a chemical vapor deposition chamber is provided. A first reactant gas is introduced through a plurality of first gas nozzles surrounding the substrate. The first gas nozzles comprise at least first and second outlet apertures. A second reactant gas is introduced through a plurality of second gas nozzles surrounding the substrate. The second gas nozzles comprise third outlet apertures. The first outlet aperture is larger than the second outlet aperture, such that the first gas nozzle with the first outlet aperture creates an increased gas flow adjacent to a determined portion of the substrate to increase deposition from the first gas on the determined portion of the substrate.

A plurality of first gas nozzles and second gas nozzles is connected to a gas distribution ring. The first gas nozzles provide a first reactant gas and comprise at least first and second outlet apertures. The second gas nozzles provide a second reactant gas and comprise third outlet apertures. The first outlet aperture is larger than the second outlet aperture. Thus, the first gas nozzle with the first outlet aperture creates an increased gas flow adjacent to a determined portion of the substrate to increase deposition from the first gas on the determined portion of the substrate, thereby reducing thickness variation and improving deposition uniformity.

Further scope of applicability of embodiments of the disclosure will become apparent from the detailed description given hereinafter. It should be understood that the detailed description and specific examples are given by way of illustration only, since various changes and modifications within the spirit and scope of the invention will become apparent to those skilled in the art from this detailed description.

### DESCRIPTION OF THE DRAWINGS

The invention can be more fully understood by reading the subsequent detailed description in conjunction with the examples and references made to the accompanying drawings, wherein

FIG. 1 is a sectional view schematically illustrating an embodiment of a deposition tool;

FIG. 2 is a plan view schematically showing an embodiment of a gas distribution ring of a deposition tool;

FIG. 3 is a plan view depicting a coverage area of the reactant gas from an embodiment of top nozzles of a deposition tool;

FIG. 4 is a bottom view showing an exemplary configuration of an embodiment of top nozzles of a deposition tool;

FIG. 5A is a sectional view showing a rough deposition layer formed on a substrate by a conventional deposition tool;

FIG. 5B is a sectional view showing a smooth deposition layer formed on the substrate by an embodiment of a deposition tool;

FIG. 6A is a plan view of the deposition layer shown in FIG. 5A; and

FIG. 6B is a plan view of the deposition layer shown in FIG. 5B.

### DETAILED DESCRIPTION

Gas distribution systems for deposition processes and methods of using the same are provided. In the interest of clarity, not all features of an actual implementation are described in this disclosure. It will of course be appreciated that in the development of any such actual embodiment, numerous implementation-specific decisions must be made to achieve the developers' specific goals, such as compliance with system-related and business-related constrains, which will vary from one implementation to another. Moreover, it will be appreciated that such a development effort might be complex and time-consuming, but would nevertheless be a routine undertaking for those of ordinary skill in the art having the benefit of this disclosure.

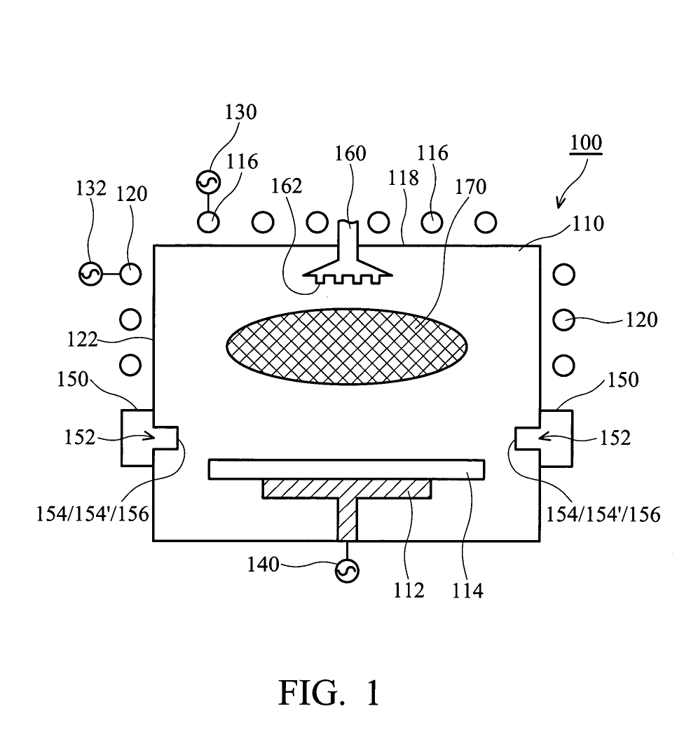

An exemplary embodiment of a deposition tool 100, shown in FIG. 1, comprising a processing chamber 110, a substrate support member 112 disposed in the processing chamber 110 and a gas delivery system (not symbolized). The processing chamber 110 may be a chemical vapor deposition (CVD) chamber, preferably, a high density plasma chemical vapor deposition (HDPCVD) chamber. The substrate support member 112 holds a substrate (or wafer) 114 disposed thereon during deposition performed in the deposition tool 100. The gas delivery system comprises a gas distribution ring 150 and a gas distribution nozzle cluster 160. The gas distribution ring 150 comprises a plurality of coplanar ports 152 in the processing chamber 110. The gas distribution ring 150 is disposed adjacent to the side surface 122 of the processing chamber 110. The gas distribution nozzle cluster 160 is disposed adjacent to the top surface 118 of the processing chamber 110. The deposition tool 100 also comprises many additional components, such as a top coil 116 adjacent to the top surface 118 of the processing chamber 110, and a side coil 120 adjacent to the side surface 122 of the processing chamber 110. The top coil 116 is coupled to a first RF power supply 130. The side coil 120 is coupled to a second RF power supply 132. A third RF power supply 140 is coupled to the substrate support member 112. The deposition tool 100 may also comprise other components, such as various electrical connections, temperature sensors, pressure sensors, mass-flow controllers and valves well known to those skilled in the relevant art. Such components are not described so as not to obscure the disclosure.

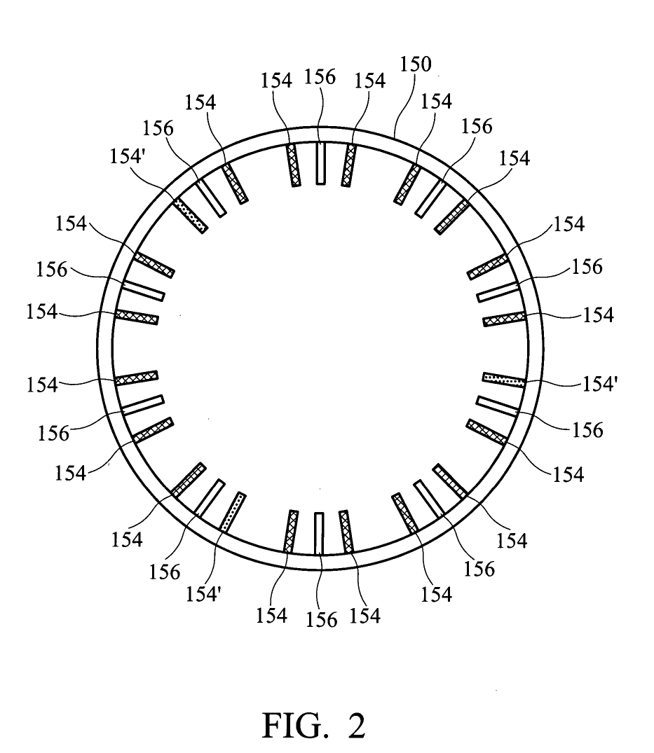

FIG. 2 is a plan view schematically showing an embodiment of the gas distribution ring 150 of the deposition tool 100. Referring to FIGS. 1 and 2, plural first gas nozzles 154/154′ and second gas nozzles 156 are connected to the gas distribution ring 150 and are each disposed in the port 152. The first gas nozzles 154/154′ are adapted to provide a first reactant gas. The second gas nozzles 156 are adapted to provide a second reactant gas. For example, in the case of forming a SiO₂ layer on the substrate 114, silane (SiH₄) and oxygen (O₂) may be introduced into the processing chamber 110. In this embodiment, SiH₄ serves as the first reactant gas and O₂ serves as the second reactant gas. The SiH₄ may be mixed with a variety of carrier gases, e.g., H₂, N₂, Ar, etc. Note that the first gas nozzles 154/154′ comprise at least first and second outlet apertures, wherein the first outlet aperture is larger than the second outlet aperture. In FIG. 2, numeral 154′ denotes the first gas nozzle with the first outlet aperture and numeral 154 denotes the first gas nozzle with the second outlet aperture. The second gas nozzles 156 comprise third outlet apertures, wherein the third outlet aperture can be equal in size to the second outlet aperture and smaller than the first outlet aperture. Accordingly, the first gas nozzle 154′ with the first outlet aperture creates an increased gas flow adjacent to a determined portion of the substrate 114 to increase deposition from the first gas on the determined portion of the substrate 114. That is, fine tuning of the first gas flow on the determined portion of the substrate 114 can be achieved to improve deposition uniformity.

Size and configuration of this embodiment are illustrated, but are not intended to limit this disclosure. The diameter of the second/third outlet aperture is about 0.03 inches. The ratio between the first outlet aperture and the second outlet aperture is between about 1.05 and 1.15, preferably, between about 1.08 and 1.12. The first and second gas nozzles 154/154′ and 156 are located circumferentially above the substrate support member 112. The first and second gas nozzles 154/154′ and 156 are located in a plane parallel to a surface of the substrate 114. In addition, the first and second gas nozzles 154/154′ and 156 are located in an alternating arrangement. For example, referring to FIG. 2, ten groups of two first gas nozzles 154/154′ and single second gas nozzle 156 are spaced around a perimeter of the processing chamber 110, wherein the second gas nozzle 156 |is disposed between the two first gas nozzles 154/154′.

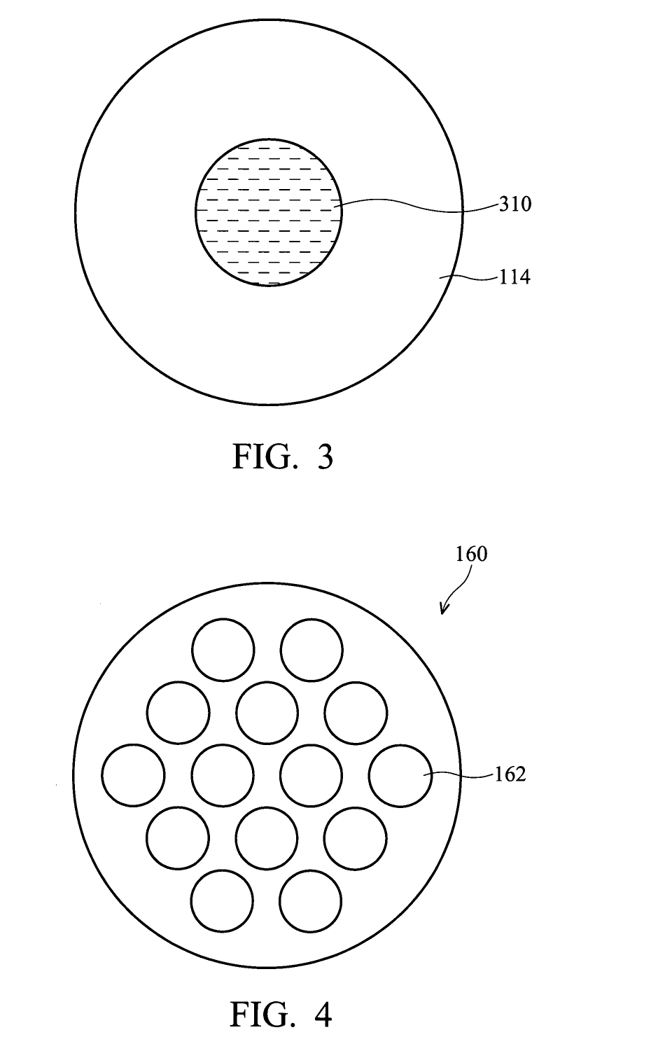

The gas distribution nozzle cluster 160 comprises third gas nozzles 162 disposed centrally above the substrate support member 112, wherein the third gas nozzles 162 serving as top nozzles 162 provides a third reactant gas. In this embodiment, the first and third reactant gases can be the same. That is, the first and third reactant gases comprise SiH₄. For example, the third gas nozzles 162 comprise an outlet aperture of about 0.03 inches, the same as the second outlet aperture. About 5-25% of the total silane gas flow may be introduced into the processing chamber 110 via the top nozzles 160. As shown in FIG. 3, the coverage area 310 of the third reactant gas from the top nozzles 162 is about 1-30% of the total area of the substrate 114. FIG. 4 is a bottom view showing an exemplary configuration of the top nozzles 162 of the deposition tool 100 of the disclosure. The number of the third gas nozzles 162 is preferably equal to or more than 4. The top nozzle 162 may have an outlet aperture of about 0.03 inches.

In FIG. 1, the deposition tool 100 may generate plasma 170 in the processing chamber 110 by application of RF power to one or both of the coils 116 and 120. The plasma 170 is generally defined as a gas containing an equal number of positive and negative charges as well as some number of neutral gas particles. A glow discharge is a self-sustaining type of plasma. As used therein, the term plasma should be understood to include any type of plasma or glow discharge. As will be recognized by those skilled in the relevant art after a complete reading of the disclosure, the disclosure may be employed using a variety of different types of deposition processes, such as, for example, an HDPCVD process. Moreover, the disclosure may be employed in forming a variety of different types of material, such as silicon dioxide, silicon oxynitride, etc. Thus, the disclosure should not be considered as limited to any particular type of deposition process or to the formation of any particular type of material unless such limitations are expressly set forth in the appended claims.

In one illustrative embodiment, a substrate 114 is processed in the disclosed processing chamber 110 for deposition of a SiO₂ layer. A representative SiO₂ layer 510/510′ is illustrated, but is not intended to limit the disclosure. For convenience, a smooth substrate 114 is shown in the drawings, although there a trench-type structure may be formed therein.

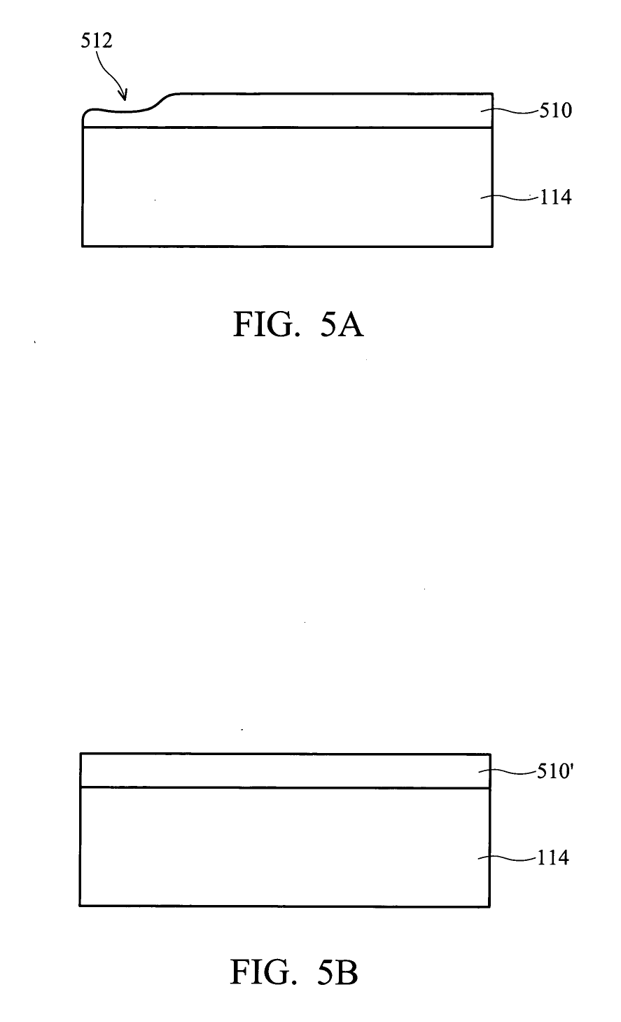

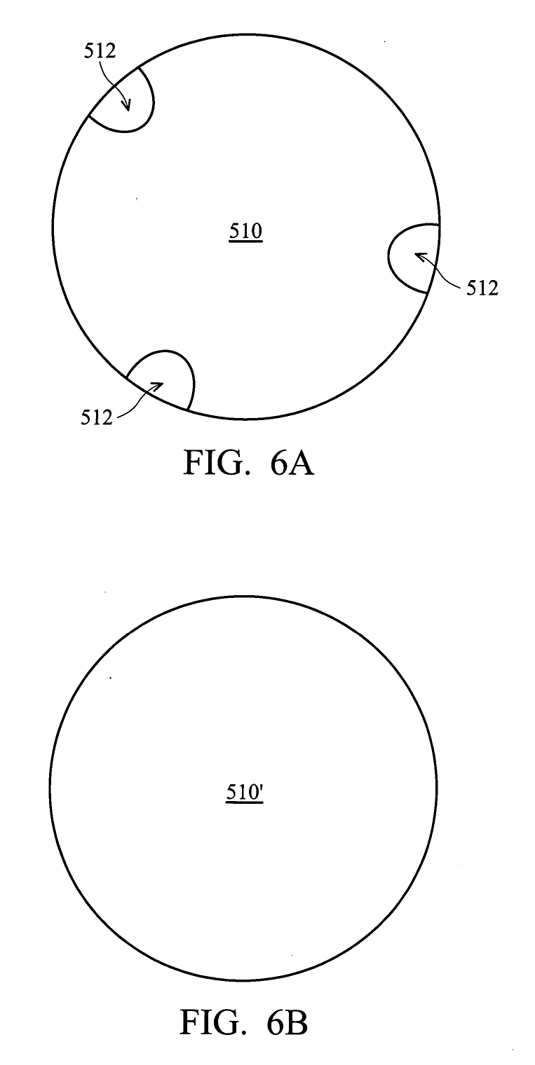

As shown in FIGS. 5A and 6A, using existing gas delivery system in current deposition tools, there tends to be a serious variation 512 in the thickness of the SiO₂ layer 510 near the edge portion of the substrate 114. Due to inherent characteristics of the processing chamber 110 itself, one or more thinner portions 512 of the SiO₂ layer 510 are often formed on the constant positions of the substrate 114 during deposition using the conventional gas delivery system. According to an exemplary method for the embodiment of the gas distribution system, the SiH₄ is introduced into the processing chamber 110 through the first gas nozzles 154/154′ surrounding the substrate 114. The O₂ is introduced into the processing chamber 110 through the second gas nozzles 156 surrounding the substrate 114. Note that the first gas nozzle 154′ with the first outlet aperture is disposed corresponding to the thinner portions 512 of the SiO₂ layer 510 formed by the previous deposition process using the conventional gas delivery system. Since the first outlet aperture is larger than the second outlet aperture, the first gas nozzle 154′ with the first outlet aperture creates an increased gas flow adjacent to the determined portion 512 of the substrate 114 to increase deposition from the SiH₄ on the determined portion 512 of the substrate 114. During deposition, a more uniform SiO₂ layer 510′ can thus be formed in the same processing chamber 110, as shown in FIGS. 5B and 6B.

An operational example is described, but is not intended to limit the disclosure. In a 300 mm substrate application, SiH₄ and argon are introduced through the first gas nozzles 154/154′ at about 110 sccm, respectively. The O₂ is introduced through the second gas nozzles 156 at about 250 sccm. The SiH₄ and argon are also introduced through the third (top) nozzles 162 at about 10 sccm, respectively. The diameter of the second/third outlet aperture is about 0.03 inches. The outlet aperture of the top nozzles 162 is about 0.03 inches. The ratio between the first outlet aperture and the second outlet aperture is about 1.1, thereby fine tuning the SiH₄ gas flow on the lower portion 512. The plasma power supplied to the first coil 116 is about 1500 W. The plasma power supplied to the second coil 120 is about 6000 W. The substrate support member 112 is biased at 6000 W. The chamber pressure is maintained at about 5-10 mT.

The embodiments provide gas distribution systems for deposition of a film. A processing chamber comprising a gas distribution ring is provided. Plural gas nozzles with a smaller outlet aperture and a larger outlet aperture are connected to the gas distribution ring, wherein the gas nozzles are adapted to provide a reactant gas forming a film with a first area and a second area overlying a substrate in the processing chamber. The gas nozzles with the smaller outlet aperture are near the first area to create a first reactant gas flow and the gas nozzles with the larger outlet aperture are near the second area to create a second gas flow larger than the first gas flow. Thus, the gas nozzle with the larger outlet aperture creates an increased gas flow adjacent to the second area of the substrate to increase deposition from the reactant gas thereon, uniforming the film thickness.

While the invention has been described by way of example and in terms of preferred embodiment, it is to be understood that the invention is not limited thereto. On the contrary, it is intended to cover various modifications and similar arrangements as would be apparent to those skilled in the art. Therefore, the scope of the appended claims should be accorded the broadest interpretation so as to encompass all such modifications and similar arrangements. What is claimed is:

1. An apparatus for depositing a film on a substrate, comprising:
a processing chamber;
a substrate support member disposed in the processing chamber, holding the substrate disposed thereon;
a gas distribution ring disposed in the processing chamber;
a plurality of first gas nozzles connected to the gas distribution ring, providing a first reactant gas and comprising at least first and second outlet apertures; and
a plurality of second gas nozzles connected to the gas distribution ring, providing a second reactant gas and comprising third outlet apertures;
wherein the first outlet aperture is larger than the second outlet aperture.

2. The apparatus according to claim 1, wherein the first gas nozzle with the first outlet aperture creates an increased gas flow adjacent to a determined portion of the substrate to increase deposition from the first reactant gas on the determined portion of the substrate.

3. The apparatus according to claim 1, wherein the processing chamber comprises a high density plasma chemical vapor deposition chamber.

4. The apparatus according to claim 1, wherein the first reactant gas comprises SiH₄ and the second reactant gas comprises O₂.

5. The apparatus according to claim 1, wherein a ratio between the first outlet aperture and the second outlet aperture is between about 1.05 and 1.15.

6. The apparatus according to claim 5, wherein the ratio between the first outlet aperture and the second outlet aperture is between about 1.08 and 1.12.

7. The apparatus according to claim 1, wherein the first and second gas nozzles are located circumferentially above the substrate support member.

8. The apparatus according to claim 7, wherein the first and second gas nozzles are located on a plane parallel to a surface of the substrate.

9. The apparatus according to claim 1, wherein the first and second gas nozzles are located in an alternating arrangement.

10. The apparatus according to claim 1, further comprising third gas nozzles disposed centrally above the substrate support member, wherein the third gas nozzles are adapted to provide a third reactant gas.

11. The apparatus according to claim 10, wherein the first and third reactant gases are the same.

12. The apparatus according to claim 11, wherein the first and third reactant gases comprise SiH₄.

13. An apparatus for depositing a film on a substrate, comprising:
a processing chamber;
a substrate support member disposed in the processing chamber, holding the substrate disposed thereon;
a plurality of ports disposed on a gas distribution ring, wherein the ports are located in a coplanar relationship in the processing chamber;
a plurality of first gas nozzles adapted to provide a first reactant gas, wherein the first gas nozzles comprise at least first and second outlet apertures and are each disposed in the port; and
a plurality of second gas nozzles adapted to provide a second reactant gas, wherein the second gas nozzles comprise third outlet apertures and are each disposed in the port;
wherein the first outlet aperture is larger than the second outlet aperture.

14. The apparatus according to claim 13, wherein the first gas nozzle with the first outlet aperture creates an increased gas flow adjacent to a determined portion of the substrate to increase deposition from the first gas on the determined portion of the substrate.

15. The apparatus according to claim 13, wherein the processing chamber comprises a high density plasma chemical vapor deposition chamber.

16. The apparatus according to claim 13, wherein the first reactant gas comprises SiH₄ and the second reactant gas comprises O₂.

17. The apparatus according to claim 13, wherein a ratio between the first outlet aperture and the second outlet aperture is between about 1.08 and 1.12.

18. The apparatus according to claim 13, wherein the first and second gas nozzles are located in an alternating arrangement.

19. The apparatus according to claim 13, wherein ten groups of two first gas nozzles and single second gas nozzle are spaced around a perimeter of the processing chamber, and the second gas nozzle is located between the two first gas nozzles.

20. An apparatus for depositing a film, comprising:
a processing chamber comprising a gas distribution ring;
a substrate disposed in the processing chamber;
a plurality of gas nozzles with a smaller outlet aperture and a larger outlet aperture connected to the gas distribution ring, wherein the gas nozzles provide a reactant gas forming a film with a first area and a second area overlying the substrate;
wherein the gas nozzles with the smaller outlet aperture are near the first area to create a first reactant gas flow and the gas nozzles with the larger outlet aperture are near the second area to create a second gas flow larger than the first gas flow, providing uniform thickness of the film;
wherein a ratio between the larger outlet aperture and the smaller outlet aperture is between about 1.05 and 1.15.
